(19) United States
(12) Patent Application Publication
(10) Pub. No.: US 2025/0308102 A1
(43) Pub. Date: Oct. 2, 2025

(54) INTEGRATION OF BUILDING INFORMATION MODELS FOR GENERATING DIGITAL RENDERINGS

(71) Applicant: Nuvolo Technologies Corporation, Paramus, NJ (US)

(72) Inventors: Ivan Kirov, Sofia (BG); Rossen Nikolov, San Gwann (MT); Khoa Nguyen Van Ho, Houston, TX (US)

(21) Appl. No.: 18/827,791

(22) Filed: Sep. 8, 2024

Related U.S. Application Data
(60) Provisional application No. 63/571,933, filed on Mar. 29, 2024.

(51) Int. Cl. G06T 11/20; G06F 30/00

(52) U.S. Cl. CPC G06T 11/203; G06F 30/00

(57) ABSTRACT

Methods and systems for rendering two dimensional representations are described. These include receiving a digital file including data of a structure comprising floors and objects, extracting, from the digital file, a first aspect associated with an object included in the at least one floor and a second aspect associated with the object, mapping the first aspect extracted from the digital file to a drawing layer, generating a first plurality of drawing files from data representing the floors of the structure, generating from the first plurality of drawing files, a second plurality of drawing files corresponding to data representing visual-graphic characteristics of the objects and the plurality of floors and a third drawing file representing perimeter characteristics of each floor, generating a geometric feature file using the third drawing file, and rendering a two-dimensional representation of the structure using the second plurality of drawing files and geometric feature file.

### CROSS REFERENCE

This application claims benefit to U.S. Provisional Application No. 63/571,933 filed Mar. 29, 2024, the entirety of which is hereby incorporated by reference herein.

### TECHNICAL FIELD

This description relates to integration of building information models for generating digital renderings, e.g., for floor plans.

### BACKGROUND

Building information models, such as Revit models, are commonly used to represent real-world constructs in the building industry. Building information models enable a three-dimensional view of a building, while other computer design models, such as computer-aided design (“CAD”) models can provide auxiliary information associated to the building, such as room name and ID information. Current building information models may not be configured to display auxiliary information. For example, a user may have to switch interfaces between a three-dimensional view and different view (e.g., a two-dimensional view) to analyze and correlate building structural information.

### SUMMARY

Systems and techniques for rendering two dimensional representations of, e.g., floor plans, from three dimensional digital content (e.g., building information models) are described. In one aspect, a method implemented by a computing device is contemplated. In this aspect, a digital file including data of a structure comprising a plurality of floors and a plurality of objects included in at least one of the plurality of floors can be received and a first aspect associated with an object of the plurality of objects included in the at least one of the plurality of floors and a second aspect associated with the object can be extracted. In aspects, the first aspect that is extracted from the digital file can be mapped to a drawing layer of a plurality of drawing layers. In aspects, the mapping causes the second aspect to be mapped to at least the drawing layer of the plurality of drawing layers. In aspects, a first plurality of drawing files from data representing the plurality of floors of the structure can be generated. In aspects, each drawing file of the first plurality of drawing files corresponding to data representing a respective floor of the plurality of floors. In aspects, a second plurality of drawing files corresponding to data representing visual-graphic characteristics of the plurality of objects and the plurality of floors can be generated from the first plurality of drawing files. Further, in aspects, at least a third drawing file representing perimeter characteristics of each floor of the plurality of floors of the structure can be generated from the first plurality of drawing files.

In aspects, the structure can correspond to a building including the plurality of floors and the digital file includes a three dimensional representation of the building and the first aspect can correspond to data representing a category of the object and the second aspect can correspond to additional data representing a family of the object. In aspects, the family can be classified as a subcategory of the category. In aspects, the drawing layer of the plurality of drawing layers can correspond to a portion of a computer-aided facilities management (CAFM) file. In aspects, each drawing layer of the plurality of drawing layers can correspond to at least one of a floor plan, an interior wall of the structure, an exterior wall of the structure, a room of the structure, an interior area of the structure, locations of security devices of the structure, the security devices comprising security cameras, capabilities of Wi-Fi hotspots in the structure, or types of furniture in the structure.

In aspects, the mapping of the first aspect with the drawing layer of the plurality of drawing layers can correspond to storing, in a database communicatively coupled to the computing device, data representative of the first aspect of the object in association with data defining the drawing layer of the plurality of drawing layers. In aspects, each of the first plurality of drawing files can have a Device Working Group (DWG) file format, each of the second plurality of drawing files can have a Scalable Vector Graphics (SVG) file format, and the at least the third drawing file can have a Drawing Interchange Format (DXF) file format.

In aspects, the geometric feature file can corresponds to a GeoJSON file format and the data included in the digital file can be associated with a three dimensional representation of the structure. In aspects, the rendering of the two-dimensional representation of the structure can comprise determining coordinate data of the plurality of floors from the at least the third drawing file, aligning data representing the second plurality of drawing files with the coordinate data, and overlaying data representing the at least one geometric feature file on at least one of the second plurality of files. In aspects, the visual-graphic characteristics can correspond to at least one of: data representing walls, data representing doors, data representing furniture, or data representing windows. In aspects, the perimeter characteristics can correspond to coordinate data of the plurality of floors that are derived from the at least the third drawing file. Additionally, in aspects, visual-graphic characteristics.

In another aspect, a system can comprise one or more computers and one or more storage devices on which are stored instructions that are operable, when executed by the one or more computers, to cause the one or more computers to perform various operations. The operations can comprise receiving a digital file including data of a structure comprising a plurality of floors and a plurality of objects included in at least one of the plurality of floors, extracting, from the digital file, a first aspect associated with an object of the plurality of objects included in the at least one of the plurality of floors and a second aspect associated with the object, mapping the first aspect that is extracted from the digital file with a drawing layer of a plurality of drawing layers, the mapping causing the second aspect to be mapped with at least the drawing layer of the plurality of drawing layers, generating a first plurality of drawing files from data representing the plurality of floors of the structure, each drawing file of the first plurality of drawing files corresponding to data representing a respective floor of the plurality of floors, generating, from the first plurality of drawing files, a second plurality of drawing files corresponding to data representing visual-graphic characteristics of the plurality of objects and the plurality of floors and at least a third drawing file representing perimeter characteristics of each floor of the plurality of floors of the structure, generating at least one geometric feature file using the third drawing file; and rendering a two-dimensional representation of the structure including the plurality of floors using the second plurality of drawing files and geometric feature file.

In yet another aspect, system comprising one or more computers and one or more storage devices on which are stored instructions that are operable, when executed by the one or more computers, can cause the one or more computers to perform various operations. The operations comprise receiving a digital file including data of a structure comprising a plurality of floors and a plurality of objects included in at least one of the plurality of floors, extracting, from the digital file, a first aspect associated with an object of the plurality of objects included in the at least one of the plurality of floors and a second aspect associated with the object, mapping the first aspect that is extracted from the digital file with a drawing layer of a plurality of drawing layers, the mapping causing the second aspect to be mapped with at least the drawing layer of the plurality of drawing layers, generating a first plurality of drawing files from data representing the plurality of floors of the structure, each drawing file of the first plurality of drawing files corresponding to data representing a respective floor of the plurality of floors, generating, from the first plurality of drawing files, a second plurality of drawing files corresponding to data representing visual-graphic characteristics of the plurality of objects and the plurality of floors and at least a third drawing file representing perimeter characteristics of each floor of the plurality of floors of the structure, generating at least one geometric feature file using the third drawing file, and rendering a two-dimensional representation of the structure including the plurality of floors using the second plurality of drawing files and geometric feature file.

Implementations of the current subject matter can include, but are not limited to, methods consistent with the descriptions provided herein as well as articles that comprise a tangibly embodied machine-readable medium operable to cause one or more machines (e.g., computers, etc.) to result in operations implementing one or more of the described features. Similarly, computer systems are also described that can include one or more processors and one or more memories coupled to the one or more processors. A memory, which can include a non-transitory computer-readable or machine-readable storage medium, can include, encode, store, or the like one or more programs that cause one or more processors to perform one or more of the operations described herein.

Computer implemented methods consistent with one or more implementations of the current subject matter can be implemented by one or more data processors residing in a single computing system or multiple computing systems. Such multiple computing systems can be connected and can exchange data and/or commands or other instructions or the like via one or more connections, including, for example, to a connection over a network (e.g. the Internet, a wireless wide area network, a local area network, a wide area network, a wired network, or the like), via a direct connection between one or more of the multiple computing systems, etc.

The details of one or more variations of the subject matter described herein are set forth in the accompanying drawings and the description below. Other features and advantages of the subject matter described herein will be apparent from the description and drawings, and from the claims. While certain features of the currently disclosed subject matter are described for illustrative purposes in relation to web application user interfaces, it should be readily understood that such features are not intended to be limiting. The claims that follow this disclosure are intended to define the scope of the protected subject matter.

### BRIEF DESCRIPTION OF THE DRAWINGS

FIG. 1 illustrates an example system configured to integrate data extracted from drawing files, in accordance with some example aspects;

FIG. 2A illustrates a flow chart of the implementation of the integration process of the present disclosure, using a plugin that is communicatively coupled to the computing system via the communication network, in accordance with some example aspects;

FIG. 2B illustrates the hierarchical relationship between categories and families;

FIG. 2C illustrates a detailed workflow of the graphical 2D sync step of the integration process as illustrated in FIG. 2A and described above, according to some aspects described and illustrated herein;

FIG. 2D illustrates a workflow of the 2D rendering step of the integration process of the present disclosure, according to some aspects described and illustrated herein;

FIG. 3A depicts an example illustration of an example implementation, display, and, operation of the plugin, according to some aspects described and illustrated herein;

FIG. 3B depicts selection of a user-selectable icon labeled “asset,” according to some embodiments described and illustrated herein;

FIG. 3C depicts selection of a user selectable icon labeled “add families,” according to some embodiments described and illustrated herein;

FIG. 3D depicts selection of a user selectable icon labeled “Map Categories,” according to some embodiments described and illustrated herein;

FIG. 3E depicts selection of a user selectable icon labeled “Auto mapping,” according to some embodiments described and illustrated herein;

FIG. 3F depicts a selection of a user selectable icon labeled “Attach to Site,” according to some embodiments described and illustrated herein;

FIG. 3G depicts a selection of a user selectable icon labeled “Data Sync,” according to some embodiments described and illustrated herein;

FIG. 3H depicts a selection of a user selectable icon labeled “Graphic Sync,” according to some embodiments described and illustrated herein;

FIG. 4 illustrates an example process for integrating BIM models as described herein for rendering two dimensional representations, according to some aspects described and illustrated herein; and

FIG. 5 shows illustrates a schematic diagram of an example computing system, according to some aspects described and illustrated herein.

Like reference numbers and designations in the various drawings indicate like elements.

### DETAILED DESCRIPTION

Building design and building construction involve architects, designers, engineers, and so forth, analyzing digital plans of various aspects of the building, refining these digital plans, and extracting various types of data from these plans to ensure that the design and construction process is implemented accurately and effectively. As the complexity associated with designing and building a structure, e.g., a multi-floor apartment complex, condominium, mall, etc., can be high, in part due to the different types of materials involved in its construction (e.g., columns of various dimensions, electrical components, piping materials, plumbing systems, and so forth), a variety of software entities and digital designing tools are utilized by designers, architects, and engineers.

These individuals spend an inordinate amount of time analyzing and editing data across these various digital file formats, many of which are proprietary to a specific software applications or entity, which results in user interaction delays and errors, inefficiencies in the building construction process, and so forth. Further, analyzing, editing, and revising digital content across various software applications is computationally burdensome, as large digital files from these software applications need to be saved and stored locally in memory of various computing devices, and often involves manually importing and inputting data (e.g., data representing digital content) from one file to another.

The systems and techniques described herein address and overcome these deficiencies. In aspects, an implementation of the digital content integration process as described herein involves a software plugin executable in a computing environment, operable to simultaneously or approximately simultaneously (e.g., within a few seconds) enable access to content from different computing environments, analyze digital content generated by a particular software application or entity stored in a particular format (e.g., a Revit file or Revit Drawing File as described in the present disclosure) and convert this digital content into a digital rendering in a format that is different from and, in aspects, more compact than the format of the previously generated digital content. Further, in addition to converting the digital content into a digital rendering in a different format, the integration process described herein operates to incorporate data from various types of additional digital content (saved in varying file formats and having different file sizes) into the digital rendering. In this way, the systems and techniques described herein reduce the need for users to import and input data from digital content stored in a particular file format, which reduces computational burdens and user errors, and improves data processing efficiencies. More importantly, the integration techniques described herein operate to extract data from a particular digital file that includes a particular type of digital content, e.g., 3D model of a building, rearrange and transform this data, and incorporate it into a different format, e.g., a 2D rendering (e.g., floor plan) of the building.

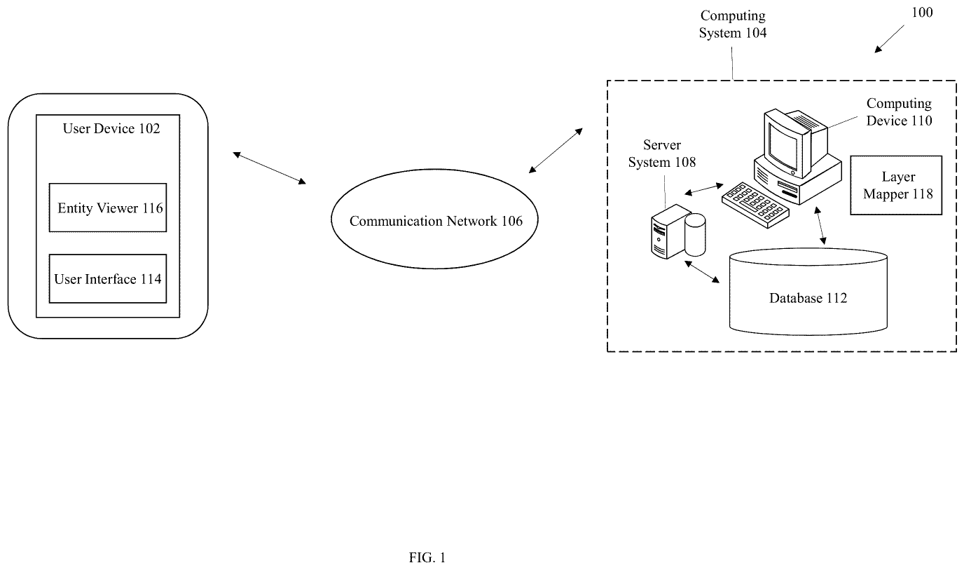

FIG. 1 illustrates an example system 100 (“system 100”) configured to integrate data extracted from drawing files, in accordance with some example implementations. The example system 100 can include a user device 102, a computing system 104, and a network 106. The computing system 104 includes a server system 108, a computing device 110, and a database 112. In aspects, each of the server system 108, the computing device 110, and the database 112 of the computing system 104 can be incorporated as part of a single device or can be correspond to separate devices that are communicatively coupled to each other, e.g., wirelessly or via a wired connection.

The user device 102 and/or the computing device 110 can be and/or include any type of processor and memory based device, such as, for example, cellular phones, smart phones, drawing filet computers, laptop computers, desktop computers, workstations, personal digital assistants (PDA), network appliances, cameras, enhanced general packet radio service (EGPRS) mobile phones, media players, navigation devices, email devices, game consoles, or an appropriate combination of any two or more of these devices or other data processing devices. The user device 102 can include a user interface 114 and an entity viewer 116. The user interface 114 can include an input interface, output interface, and communication interface. The input interface includes a component that permits user device 102 to receive information, such as via user input (e.g., a touchscreen display, a keyboard, a keypad, a mouse, a button, a switch, a microphone, a camera, and/or the like). Additionally or alternatively, in some embodiments input interface includes a sensor that senses information (e.g., a global positioning system (GPS) receiver, an accelerometer, a gyroscope, an actuator, and/or the like). The output interface includes a component that provides output information from user device 102 (e.g., a display, a speaker, one or more light-emitting diodes (LEDs), and/or the like). In some embodiments, communication interface includes a transceiver-like component (e.g., a transceiver, a separate receiver and transmitter, and/or the like) that permits user device 102 to communicate with other devices via a wired connection, a wireless connection, or a combination of wired and wireless connections. In some examples, the communication interface permits user device 102 to receive information from another device and/or provide information to another device. In some examples, communication interface includes an Ethernet interface, an optical interface, a coaxial interface, an infrared interface, a radio frequency (RF) interface, a universal serial bus (USB) interface, a Wi-Fi® interface, a cellular network interface, and/or the like. The entity viewer module 116 can be configured to enable visualization of drawing files. The user interface 114 can enable an entry of a user input to initiate an authenticated session, during which customized visualization of drawing files can be enabled. As shown in FIG. 1, the user device 102 can be communicatively coupled with the server system 108, via the network 106.

In the example of FIG. 1, the server system 108 is intended to represent various forms of servers including, but not limited to a web server, an application server, a proxy server, a network server, and/or a server pool. The server system 108 can accept requests for services of applications that enable tenant specific customization and provide such services to any number of user devices over the network 106.

The database 112 stores data that is transmitted to, received from, and/or updated by the server system 108 and/or the user device 102. In some examples, database 112 includes a storage component, such as a hard disk (e.g., a magnetic disk, an optical disk, a magneto-optic disk, a solid state disk, and/or the like), a compact disc (CD), a digital versatile disc (DVD), a floppy disk, a cartridge, a magnetic tape, a CD-ROM, RAM, PROM, EPROM, FLASH-EPROM, NV-RAM, and/or another type of computer readable medium, along with a corresponding drive. In some embodiments, the database 112 stores data drawing files (three-dimensional (3D) and/or two-dimensional (2D) drawing files) and data associated with 2D and/or 3D maps of at least one area of an entity (building). The database 112 can be include a multitenant database architecture (e.g., multitenant database containers (MDC)), such that each tenant of the server system 108 (using a respective user device 102) can customize respective drawing files stored by the database 112 and can be served by separate instances of the server system 108. In some implementations, the database can include an on-premise database system (e.g., system databases, tenant databases, etc.), servers (e.g., name server(s), index server(s), script server(s), etc.). The database 112 can store multiple drawing files that can be accessible (e.g., via queries, procedure calls, etc.) by a layer mapper 118 of the computing device 110, in response to a customization and/or a visualization request received from the user device 102 and by cloud-based software applications. The database 112 can include a runtime database that holds most recent database drawing files and respective two-dimensional floor plans to enable customization of application settings defining application instances, according to tenant preferences, transmitted via the network 106.

The network 106 includes one or more wired and/or wireless networks. In an example, network 106 includes a cellular network (e.g., a long term evolution (LTE) network, a third generation (3G) network, a fourth generation (4G) network, a fifth generation (5G) network, a code division multiple access (CDMA) network, etc.), a public land mobile network (PLMN), a local area network (LAN), a wide area network (WAN), a metropolitan area network (MAN), a telephone network (e.g., the public switched telephone network (PSTN), a private network, an ad hoc network, an intranet, the Internet, a fiber optic-based network, a cloud computing network, etc., a combination of some or all of these networks, and/or the like.

With continued reference to FIG. 1, one or more functions will be described as being performed by the example system 100. The number and arrangement of the components and/or devices of the example system 100, shown in FIG. 1 are provided as an example. There may be additional systems and/or devices, fewer systems and/or devices, different systems and/or device, or differently arrangement systems and/or devices than those shown in FIG. 1. Furthermore, two or more systems and/or devices show in FIG. 1 may be implemented within a single system or a single device, or a single system or a single device shown in FIG. 1 may be implemented as multiple, distributed systems or devices. Additionally, or alternatively, a set of systems or a set of devices (e.g., one or more systems, one or more devices) of the example system 100 may perform one or more functions corresponding to different types of drawing files, described as being processed by another set of systems or another set of devices of the example system 100.

The example system 100 (e.g., the layer mapper 118) can be used to process various types of digital content. The digital content can include building information models (e.g., Revit files), as computer-aided facility management (“CAFM”) layers, and computer-aided design (“CAD”) files, Scalable Vector Graphics Files, .DWG files, .DXF files, GeoJSON Files, and so forth. The building information models include three-dimensional (3D) representations of a geographic entity, such as a building or physical location Each layer of a respective drawing file can correspond to an item of the geographic entity. For example, each of the multiple layers can correspond to a respective item such as a floorplan of a floor in the building, a room of a floor in the building that is represented by the floorplan, or an interior or exterior wall of a room included in the floorplan.

In some implementations, the example system 100 is configured to implement a framework for interpreting and extracting graphics and data elements of an example drawing file to digitally render the items of a building for presentation to the user device 102. The graphics and data elements cooperate to present a digital representation of the items in an application program used to generate the drawing file. For example, the drawing file can be a DXF file generated by an example CAD program and encode data representations of real-world items, such as the example items described above. Example drafting/design programs may include various commercial CAD tools or related drafting software applications.

Data representations of real-world items in separate or distinct drawing files, or even across distinct layers of a drawing file, can be encoded and arranged differently based on design preferences and drafting protocols used in the CAD program. The variety of encoding ways used for data representations can complicate the extraction of particular types of information from a drawing file. To address these challenges, the example system 100 can be operable to execute a subset of the techniques for implementation of the integration process described herein.

For example, user device 102 can receive an input (via the user interface 114) including a selection of one or more drawing files to be retrieved from the database 112, processed for data integration, and customized according to a selected customization (retrieved from the database 112 or received as an input by the user device 102). The drawing files can be processed by the layer mapper 118 (e.g., included in the computing system 104). In some implementations, the layer mapper 118 obtains the drawings files based on input from user device 102 that is received by way of user interface 102. The layer mapper 118 can receive or obtain the drawing files independent of input from user device 102 but execute its file audit and data processing operations based on user input received by way of user interface 102.

In some implementations, the layer mapper 118 automatically imports the drawing files from the database 112 and automatically executes its layer mapping and data processing operations. The file storage location may be internal or external to the example system 100. For example, the file storage location may correspond to the database 112 that includes database drawing files for storing information about space hierarchies of a geographic location. The space hierarchies may define a physical layout of a region, campus, site, or floor of the geographic location.

In some implementations, the layer mapper 118 is configured to receive or obtain, as inputs, each of the drawing files and generate a layer mapping file based on processes performed on the received inputs. The processes may be executed by the layer mapper 118 based on a mapping template, a user input defining customizations, received from the user device 102, or both. In some implementations, the layer mapper 118 generates a layer mapping file based on instructions or commands specified by a space/system administrator (“space admin”) that indicate operations to be performed on the drawing files. The instructions can define or indicate layers of the drawing files as well as computer-aided facility management (“CAFM”) layers stored among database drawing files of the example system 100.

The layer mapper 118 can select a mapping template that defines protocols for aggregating sets of data values of the different layers with respect to instructions and database values of the CAFM layers as indicated by a space admin. For example, the layer mapper 118 can receive layer data for multiple layers of a drawing file, where the layer data specifies information for items such as hallways, offices on a floor, types of furniture in the offices, locations of security cameras on the floor, or capabilities of various Wi-Fi hotspots on the floor. The layer mapper 118 can use the template protocols to aggregate values for types of office furniture for a particular office while, for example, filtering out data values that indicate locations of security cameras on a floor.

In more detail, for one or more drawing files, the layer mapper 118 can map portions of the layer data for different layers, such as furniture in the offices, to a hierarchy of the CAFM layers (e.g., indicating each office on a floor) as defined in the database to produce a grouping of CAD layers. For example, the grouping of CAD layers can represent a group of offices on a particular floor of a building along with each item of furniture in each office on a given floor. In some implementations, the layer mapper 118 determines the mapping between the 3D model, the drawing layers and the CAFM layers at least by processing data values of the different drawing layers (e.g., received inputs) against the protocols defined by the mapping template and with reference to any grouping preferences indicated by the user device 102 or the space admin.

The layer mapper 118 generates a layer mapping output represented by CAD layers based on the mapping between layers of the drawing files and the CAFM layers in a database drawing file of the example system 100. In some implementations, the layer mapper 118 generates a layer mapping output that aggregates information such as data values and entity records of the received inputs based on the determined mapping of the layers. The layer mapper 118 can generate a layer mapping output that groups layer types such as the offices, the Wi-Fi hotspots, and the types of office furniture for visual rendering to an end-user, e.g., user device 102 or a different user.

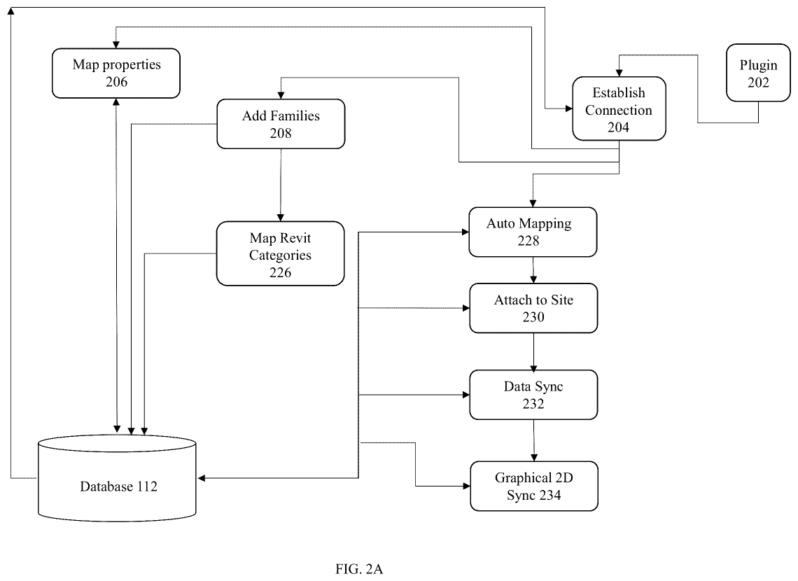

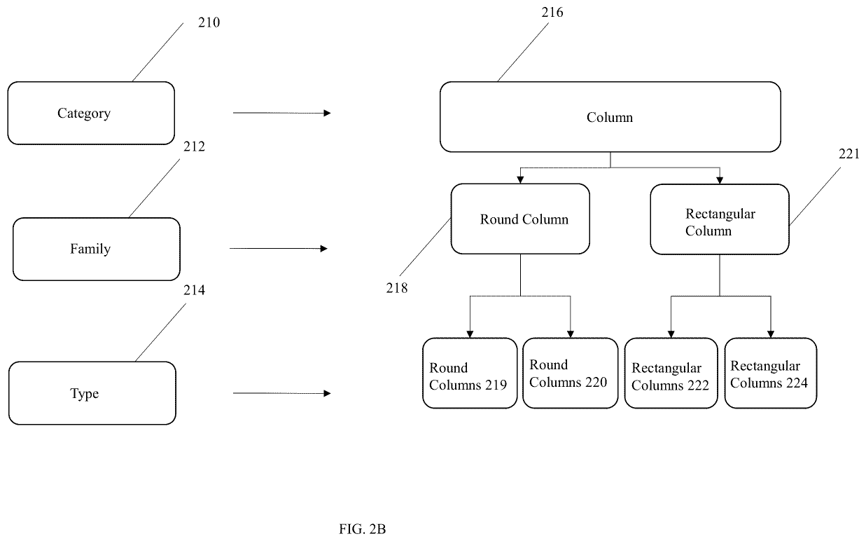

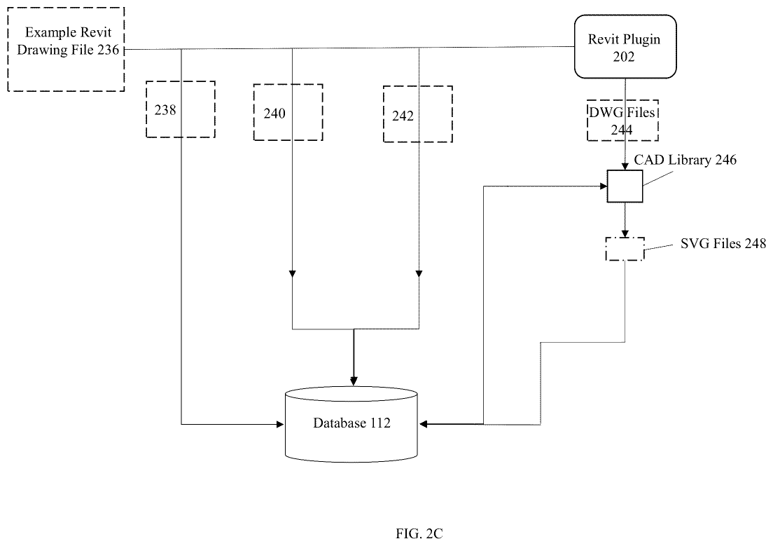

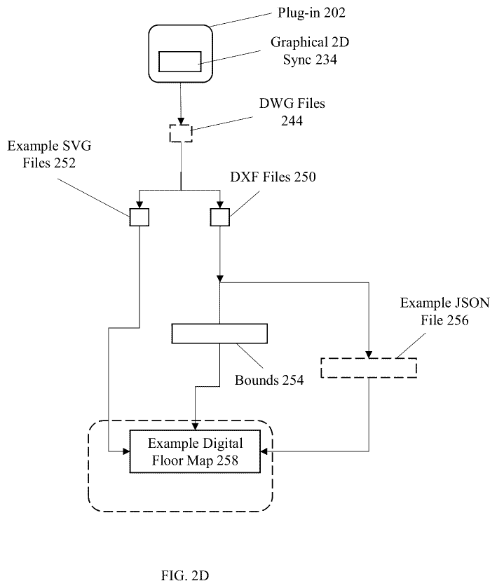

The respective outputs of the layer mapper 118 may be stored in the database 112 and later accessed to generate a preview of the data and graphics for a layer or floorplan before final visual rendering. Additionally, the example system 100 can generate a merged graphics layer by overlaying dimensional coordinates of a GeoJSON file over dimensional coordinates of a scale vector graphics (“SVG”) file or one or more image tiles generated from the SVG file. The merged graphics layer can be used for presentation of the preview of the data and graphics for the layer or floorplan, presentation of a final version of the layer or floorplan, or both. In some implementations, the example system 100 generates the merged graphics layer based on intelligent analytics and calculations related to spatial coordinates and bounds for respective coordinate systems of the SVG file and GeoJSON file or the one or more image tiles and the GeoJSON file. This is described in more detail with reference to FIGS. 2A-2D.

Additionally, it is noted that the integration process, as described herein, includes efficient processing of large data sets within secure settings (e.g., during authenticated sessions). The integration process, which involves extracting and transforming data from one digital file format to another entirely different digital file format, cannot be performed manually, e.g., using a pen and paper. The results of the integration process enable visualization of floor plans configured according to a selected site of a network of facilities. The integration process includes an auto mapping operation that enables secure processing and visualization of floor plans with selected object categories. The secure processing includes prevention of corruption of received models. It is noted that a plurality of ways of implementing secure processing sessions (e.g., various types of authenticated sessions) are contemplated. For example, basic authentication, session authentication, token based authentication, and so forth. Further, the implementation and verification of the authentication session can occur in a single device (e.g., a server) or using two devices operating in conjunction (e.g., a server that is communicatively coupled with multiple devices through a communication network).

FIG. 2A illustrates a flow chart of the implementation of the integration process of the present disclosure, using a plugin 202 that is communicatively coupled to the computing system 104 via the communication network 106, as described in some aspects described and illustrated herein. In aspects, a plugin 202 can be integrated as part of a third-party software entity such as, e.g., Building Information Modeling (“BIM”), Computer-Aided Design Software (e.g., AutoCAD), and a plurality of other comparable software programs. In aspects, the plugin 202 can be a software entity that operates as an integrated part of the third-party software entity. In aspects, the plugin 202 and the third-party software application can be executed on the user device 102. The user device 102 can be independent from the computing system 104 and communicatively coupled to the computing system 104 via the communication network 106. In aspects, the plugin 202 can be positioned as part of a digital content displayed on a user interface of the user device 102. For example, the plugin 202 can be integrated as part of a digital document associated with and/or generated by the third party software, e.g., BIM software, CAD software, and so forth.

In aspects, the plugin 202 can be displayed as a user-selectable icon or tab positioned on some portion of the digital content generated by the third party software accessible to a user on user interface displayed on, e.g., a monitor, smartphone, laptop, and so forth. Upon selection of the plugin 202, e.g., via a touch based user input or other forms of user input, a plurality of additional user selectable icons can be displayed. For example, an example set of additional user selectable icons can include “map properties”, “add families”, “map categories,” “auto mapping,” “attach to site,” and one or more icons operable to enable syncing actions. In aspects, the plugin 202 can also include an icon that enables direct access to and syncing with one or more proprietary software entities and/or platforms operating as part of and being executed on the computing system 104.

Upon selection of the plugin 202, the third party software of which the plugin 202 is a part, can establish a connection 204 (e.g., a wireless connection via the communication network 106) with the one or more proprietary programs and/or platforms operating as part of the computing system 104. An authentication session can occur prior to the establishing of such as session using the one or more of the authentication techniques described above. The connection enables the sharing of data (approximately in real-time) between one or more types of digital content files (e.g., contents of a Revit file) executed on and accessible via the third party software and one or more proprietary software entities and/or platforms operating on the computing system 104. As described herein, the term “real-time” can refer to, e.g., processing, execution, implementation, data transmission and reception, and so forth, which can occur simultaneously or within a short period of time (e.g., a few seconds). For example, the sharing of data between the third party software and the one or more proprietary software entities and/or platforms can be initiated and implemented within a few seconds.

In aspects, a Revit drawing file having an extension of .rvt (also referred to in the present disclosure as a Revit file) can be generated using a 4D BIM software application. The 4D BIM software application can be a modeling application that can be used to generate a 3D model of a building, which can be analyzed relative to time, scheduled, and building progress related metrics. In aspects, a Revit file comprises a variety of details regarding a particular building that is represented in 3D. These details can include data of the architecture and design of a building, the installation of mechanical, electrical, and plumbing systems at various locations in the building, and so forth. In aspects, the plugin 202 selection initiates integration of the Revit file with one or more proprietary applications and platforms operating on the computing system 104 such that one or more aspects of the Revit drawing file is transformed, approximately in real time, into a two-dimensional rendering. Such a transformation includes extracting data from the Revit file, extracting data from the database 112 communicatively coupled to the computing device 110 and the server system 108 of the computing system 104 (and one or more additional digital files (associated with file formats that vary from the Revit file)), and generating a 2D digital file (e.g., a 2D floor plan) that includes at least some data from the Revit drawing file, at least some data from the database 112, and at least some data from one or more of the additional digital files.

For example, as stated above, if the Revit drawing file includes data of, e.g., a 100-floor building with multiple rooms on each floor, stairwells, security cameras, WiFi components, furniture, and so forth, the implementation of the integration process described herein, enables for the generation of a 2D rendering of each floor of the 100-floor building that includes (1) various features, labels, and descriptions of the proprietary application and/or platform operating as part of the computing system 104, in combination with (2) the data (data representative of multiple rooms on each floor, security cameras, stairwells, and so forth) included in the Revit drawing file. In other words, in aspects, the implementation of integration process can transform some or all of the data included in the 3D Revit drawing file into a 2D rendering approximately in real time. Further, the 2D rendering can include the data of the 3D revit file integrated with or displayed, in some way, in combination with labels, feature descriptions, and so forth, specific to one or more additional digital files and to the proprietary application and/or platform operating on the computing system 104. FIG. 2A illustrates a flow chart, which details this integration process.

As shown in FIG. 2A, selection of a Map Properties 206 icon (e.g., user selectable icon), initiates a process that results in the integration or association of data extracted from the Revit drawing file with particular data included as part of the document database 112 of the computing system. For example, data representing one or more properties of the 3D model represented by the Revit drawing file can be associated with one or more data fields specific to the software application (e.g., proprietary software application) and/or platform (e.g., proprietary platform) operating as part of the computing system 104. In aspects, as stated above, this mapping process is part of a series of steps that enables the generation of a two-dimensional (2D) representation (e.g., 2D floormap) of the 3D model represented by the Revit drawing file in a memory efficient manner. For example, a 3D model of a structure (e.g., a building) represented by the Revit drawing file, which includes hundreds of floors, with a number of rooms on each floor, can be processed using the integration process such that a 2D floor (e.g., 2D floorplan) can be generated, approximately in real time, that captures aspects of at least some items on each room of each floor of the building. In other words, in aspects, a majority of the features included the 3D model of the building can be represented as a 2D floorplan as a result of the implementation of the integration process described herein.

In operation, selection of the Add Families icon 208 (e.g., a user selectable icon), initiates a process that includes extracting various types of data and digital content from the Revit drawing file and importing and storing this data in the database 112 of the computing device 110. The term “families” represents a data classification type specific to the software application utilized to generate the Revit drawing file and represents a collection of similar elements, e.g., elements that share similar dimensions, operate in a similar manner, and so forth. In aspects, the types of families can include: system families, loadable or component families, in-place families, annotation families, hosted families, and imported families.

System families can include descriptors of elements that are pre-defined in the software application, e.g., walls, ceilings, floors, pipes, ducts, and so forth. In aspects, these elements and the descriptors of these elements can be associated with static parameters. Additionally, in aspects, these elements and the associated descriptors are predefined in the software application and cannot be altered by users. Loadable or component families can include elements that can be installed in a building, e.g., doors, windows, furniture, water heaters, plumbing fixtures, sprinklers, flex ducts, air terminals, beams, various forms of connectors, trusses, braces, and so forth. In contrast with system families, loadable or component families can be generated by a software that is separate and distinct from the software application used to generate the Revit drawing file and be imported into the software application used to generate the Revit drawing file. In aspects, the loadable or component families are associated with a “RFA” file.

In aspects, in-place families can include custom components that are based on specific project and/or building requirements and share properties that are similar to loadable or component families. Annotation families are present in both system and loadable families and include certain element descriptors such as dimension style, levels, etc. Hosted families can include an element that can provide support for another element. One or elements in the component of loadable family can be classified within the hosted family if it is installed in association with or on an element in the system family. For example, a lighting fixture that is installed on a ceiling can be classified within a hosted family because it provides some additional structure to the ceiling. Imported families can correspond to digital content files generated by a software application different from the software application used to generate the Revit drawing file, which are imported into the software application used to generate the Revit drawing file. For example, the digital content files can be generated by one or more of the following software application: Rhinoceros 3D, Solidworks, Creo, AutoCAD, Microstation, Sketchup, and a number of other comparable applications.

In operation, selection of a Map Revit Categories icon 210 initiates the process of extracting categories data from the software utilized to generate and/or access the Revit file and sharing the extracted data with the computing system 104. In aspects, categories can be broadly classified as annotation categories and model categories. These categories are predefined in the software application used to generate and/or access the Revit drawing file and may not be altered. Model categories include various elements such as walls, doors, floors, stairs, columns, beams, while annotation categories include elements such as text, dimensions, tags, linear dimension styles, and so forth.

FIG. 2B illustrates the hierarchical relationship between categories and families. As illustrated, category 210 can be positioned at a topmost position in the hierarchy, with family 212 being positioned a level underneath category 210, and type 214 being positioned a level under Family 212. Further, it is noted that a particular component sharing the properties of a particular type (e.g., type 214) can be classified in association with the type. For example, if a particular category corresponds to column 216 (e.g., columns or beams installed as structure support for a building), then every type of column used for the building can be classified under respective families within the category 210 of column 216. For example, round column 218 and the rectangular column 220 can be classified as distinct families within the category 210 of the column 216. Further, as illustrated in FIG. 2B, each of the families of round column 218 and rectangular column 221 include various types of round and rectangular columns, e.g., round column 219, round column 220, rectangular column 222, and rectangular column 224. In aspects, round columns 219 and 220 can have varying dimensions, e.g., round columns 219 can have a diameter of 600 mm while round columns 220 can have a diameter of 400 mm. Similarly, rectangular columns 222 can have an area of 300 mm while rectangular columns 224 can have an area of 200 mm.

Returning to FIG. 2A, after categories data is communicated to the computing system 104, this data is stored in the database 112 and accessible, approximately in real time, by the layer mapper 118 executed on the computing device 110 and the server system 108. In aspects, the categories data can be accessed, simultaneously and/or sequentially, by the layer mapper 118 and the computing device 110. In aspects, selection of the Map Revit Categories 226 enables corresponding or associating each of the categories included as part of the Revit drawing file (e.g., Annotation categories, Model categories, etc.) with a specific computer-aided facility management (“CAFM”) layer stored in the database 112. In particular, each category of the Revit drawing file can be associated with a specific CAFM layer in a hierarchy of a plurality of CAFM layers. The CAFM layers described herein can be generated by the software entity executed on the computing system 104 and/or accessible, by the computing system 104, from a cloud server external to the computing system 104. In aspects, each CAFM layer can correspond to, e.g., data representative of each room or office on a floor in addition to each floor of a building. As such, the selection of the Map Revit Categories 226 results in (1) the extraction of data of each floor of, e.g., a 100-floor building, from the Revit drawing file and each room on each floor of the building, and (2) the associating of this extracted data with a specific CAFM layer of the software application. Further, each category of the Revit drawing file can also be associated with one or more Computer-Aided Design (CAD) layers. Additionally, it is noted that these CAD layers are associated with or mapped in relation to the CAFM layers as well.

In aspects, selection of an Auto Mapping 228 icon, as illustrated in FIG. 2A, associates various attributes specific to the software entity executed on the computing system 104 with at least some of the data extracted from the Revit drawing file. In aspects, the auto mapping process can be implemented after the processes that result from the selection of the Add Families 208 icon and the Map Revit Categories 226 icon. In other aspects, the auto mapping process can be implemented approximately simultaneously with the implementation of the processes that result from the selection of the Add Families 208 icon and the Map Revit Categories 226 icon.

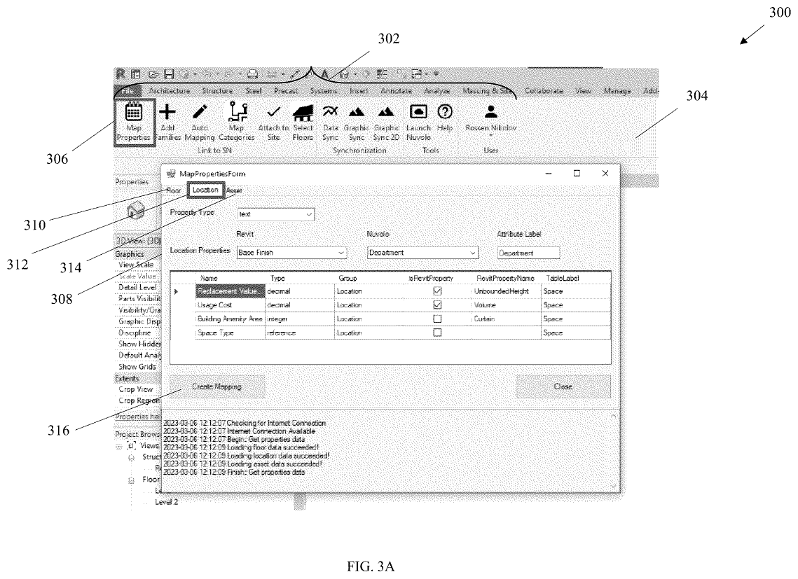

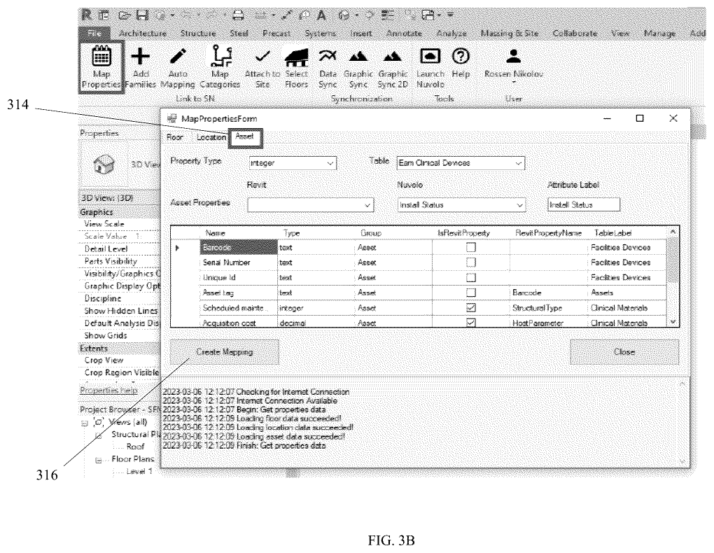

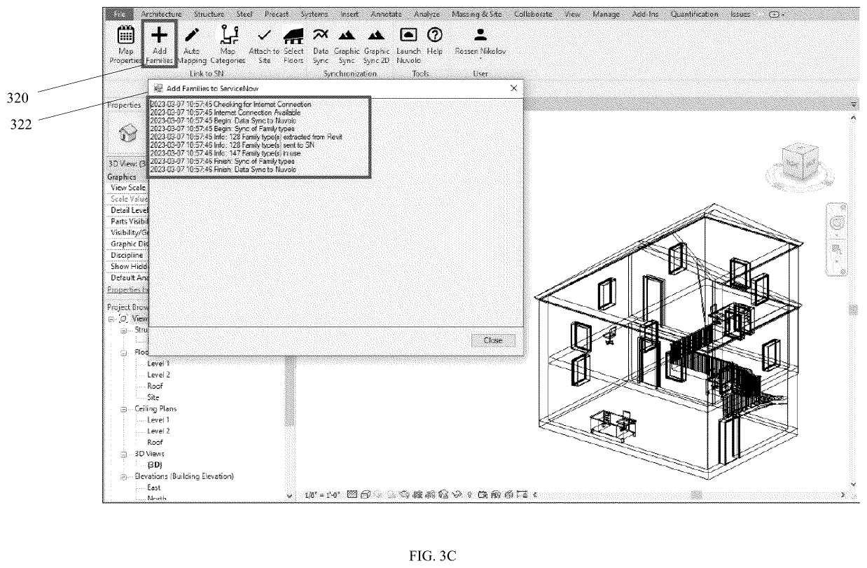

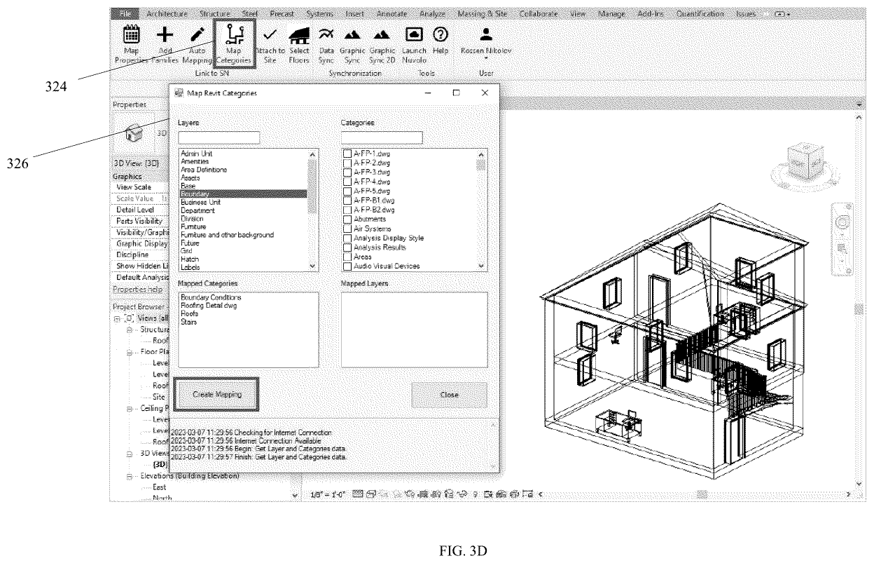

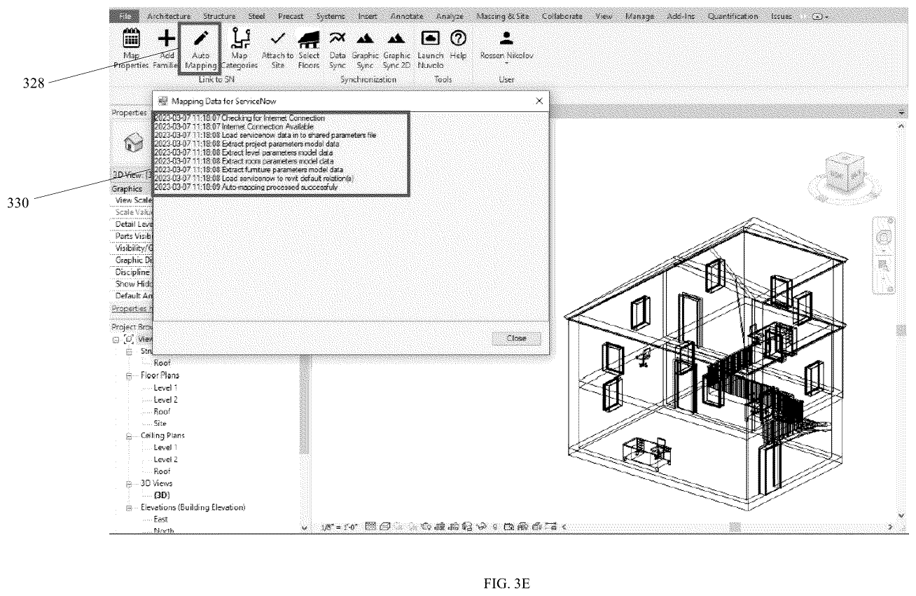

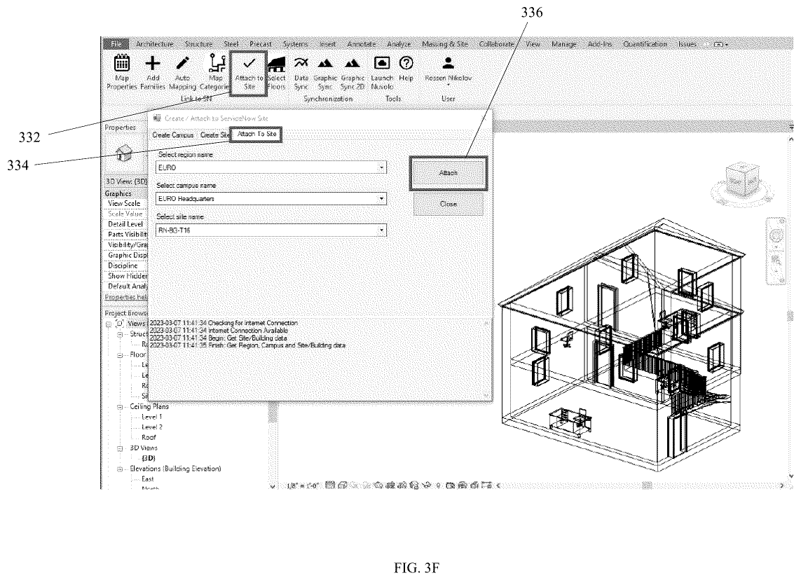

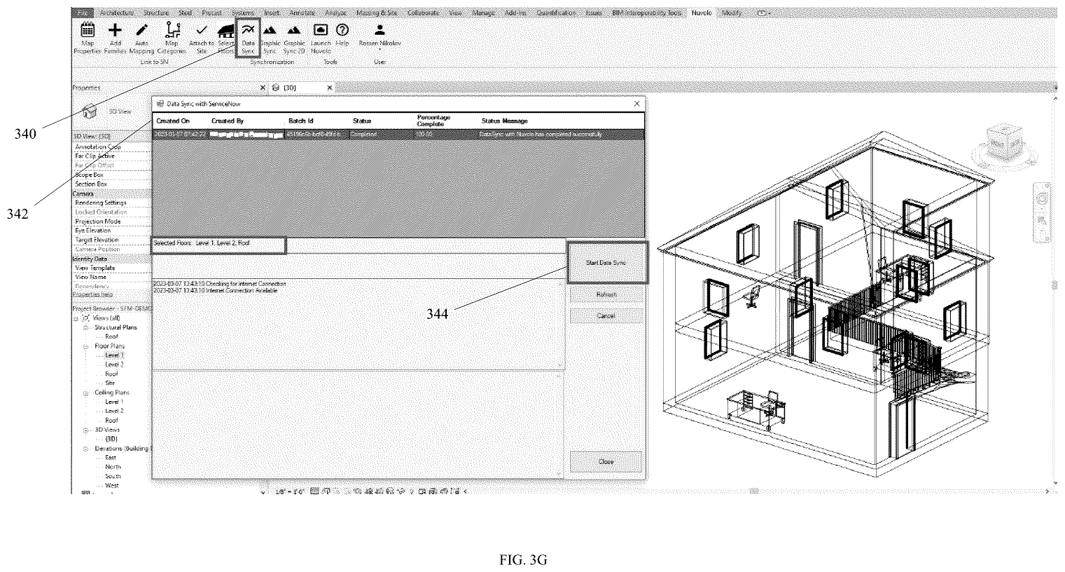

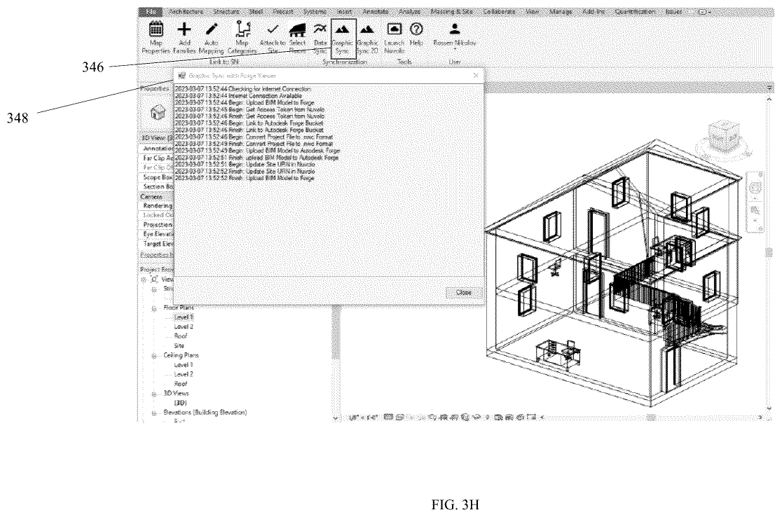

In aspects, the selection of the Attach to Site 230 icon, causes the linking or associating of the data extracted from the Revit drawing file with specific data structures of the software application executed on the computing device 110, as illustrated in FIG. 3F and described later on in this disclosure. For example, data extracted from the Revit drawing file can be corresponded with or mapped in association with a region, a campus, a site or geographic location, and so forth. The associating or corresponding of the data extracted from the Revit drawing file with the data structures specific to the software entity is stored in the database 112, specifically as part of one or more tables stored in the database 112 that represent spatial hierarchies such as, e.g., regions, campuses, sites, floors, locations, and other assets. In aspects, the one or more tables can correspond to a look-up table that can be accessed by the software entity, automatically and without user intervention, upon selection of the Attach to Site 230 icon.

Further, in aspects, selection of a data sync 232 icon initiates a process of integrating all of the pertinent data for rendering a 2D representation (e.g., 2D floor plan) of the digital content included in the 3D representation of the Revit drawing file. Specifically, the data representing categories, families, and any additional visual-graphic data classified within the families are linked to regions, campuses, sites, floors, location, and other asset descriptors and elements specific to the software entity executed as part of the computing system 104. The linking can involve association or transformation of data, integration of various data structures, and the customization of digital content in the Revit drawing file a specific data structure specific to the software entity executed on the computing system 104. Further, the extracted data relates to the categories, families, and any additional data of elements classified within these respective families are also linked to one or more CAD layers and CAFM layers (which can represent data of a spatial hierarchy of floors of a building, and so forth).

Next, in aspects, selection of graphical 2D sync icon 234 initiates a process of generating a rendering, for display on the user interface 114 of the user device 102, of all of the data extracted from the Revit drawing file (e.g., a 3D digital representation of a building) as a 2D rendering. In aspects, the generated 2D rendering includes data (digital labels, digital textual descriptions, images, icons, and so forth) of regions, campuses, sites, floors, locations, and other elements displayed in conjunction with, alongside, and in proximity with data extracted from the Revit drawing file. For example, digital labels and other digital textual descriptions of floors, which are proprietary to the software entity executed on the computing device 110 and which are independent of and external to the Revit drawing file, can be positioned alongside data from the Revit drawing file. In short, the result of the graphical 2D sync process is the transformation of the Revit drawing file, which includes 3D data representative of a building or a structure, into a 2D rendering, approximately in real time (e.g., within a few seconds).

FIG. 2C illustrates a detailed workflow of the graphical 2D sync step of the integration process as illustrated in FIG. 2A and described above, according to some aspects described and illustrated herein. As illustrated in FIG. 2C, in aspects, the Revit drawing file (e.g., example Revit drawing file 236) can be opened using, e.g., software entity external to the software entity executed on the computing system 104. Thereafter, in aspects, a user may select the Revit Plugin 202 and follow up with a selection of Map Properties 206 icon, Add Families 208 icon, and the Map Revit Categories 226 icon. In aspects, a selection of these icons can, automatically and without user intervention, initiate a series of steps as illustrated in FIG. 2B and described above, namely the extraction of data representative of all categories and all families included in the Revit drawing file and communication of the extracted data to the computing system 104. In aspects, the extracted data 238 is routed to and stored in the database 112, which is communicatively coupled to the computing device 110 and the server system 108. In aspects, a next step in the integration process can include a mapping or corresponding of CAD layers with the CAFM layers (240) followed by a mapping or associating of data representative of each category of the categories present in the Revit drawing file with a respective CAFM layer (242). As stated above, a set of CAFM layers can represent data of, e.g., a spatial hierarchy of floors of a building. Thereafter, another step in the integration process can include the plugin 202 generating, responsive to the selection of the graphic 2D sync icon 234, one or more DWG files 244 (e.g., a CAD file) that is generated for each floor of, e.g., a multi-floor building, the 3D representative of which is represented in the Revit drawing file. In aspects, the one or more DWG files 244 can be routed to and included as part of a CAD library 246, which is stored in the database 112.

In aspects, data associated with categories, which is extracted from the Revit drawing file, and which is mapped to or corresponded with distinct CAFM layers, can be accessed from a memory location in the database 112 and transferred to another memory location in the database, namely memory locations that are associated with or store information related to the data included in the CAD library 246. In this way, one of the steps in the integration process can include incorporating, within one or more CAD files in a CAD library, the data from the one or more DWG files 244 in direct association with data associated with the categories. As previously stated, data representative of each category is mapped in association with a respective distinct CAFM layer of a plurality of CAFM layers. Yet another step in the integration process includes generating, in aspects, a plurality of scalable video graphics or SVG files 248 in an amount equal to a particular number of CAFM layers. In aspects, the generated SVG files 248 are stored in various memory locations in the database 112 and stored in association with various space tables of the proprietary software application that operates on the computing device 110. As stated above, an SVG file stands for a Scalable Vector Graphics file (associated with an XML-based vector image format) that defines two-dimensional graphics, namely visual digital content (e.g., interactivity and animation).

FIG. 2D illustrates a workflow of the 2D rendering step of the integration process of the present disclosure, according to some aspects described and illustrated herein. As illustrated in FIG. 2D and as described above, upon selection of the graphical 2D sync icon icon 234, one or more DWG files 244 are generated such that at least one DWG file is generated for each floor of, e.g., a multi-floor building. As stated above, a DWG file corresponds to a binary file format based file that is operable to store two dimensional and three dimensional design data and metadata. In aspects, using the generated one or more DWG files 244, DXF files 250 and example SVG files 252 are generated. In aspects, the SVG files 252 can be representative of, as described above, corresponding CAFM layers, which in turn are associated with respective CAD layers. The data represented by the example SVG files 252 comprise visual graphic information (visual-graphic characteristics) of various aspects of a floor map including, e.g., walls, doors, furniture, exit signs, stairs, windows, and so forth. In aspects, the generated example SVG files 252 are stored in the database 112. In aspects, the DXF files 250 comprise interactive layer information of, e.g., a floor map. For example, data representative of space code and graphical shape information including, e.g., data of XY coordinates of rooms, can be included as part of the DXF files. Thereafter, in aspects, the generated DXF files 250 can be transformed or converted into files of a different format, e.g., GeoJSON file. A geometric feature file includes a collection of data that represents various geometric features, which correspond to various shapes, e.g., rectangle, square, circle, etc. These features, as included in the geometric feature file, can be utilized to represent portions of various spaces, locations, regions, and geographical features. For example, the geometric features can represent a perimeter or the bounds of a floor on a multi-floor building, districts of a city, borders of a state, and so forth. Further, in aspects, data representative of bounds 254 or dimensions of a floor map (perimeter characteristics), which corresponds to coordinates of the floor map, are extracted from the DXF files 250. It is noted that, in aspects, a single DXF file instead of multiple DXF files 250 can be generated. In aspects, the step of rendering the 2D floor plan includes combining or aligning the example SVG files 252 with the bounds 254 (defined by the XY coordinates of one or more rooms), and overlaying, e.g., the example GeoJSON File 256 over the example SVG files 252. In this way, in aspects, a 2D rendering of a floor plan (an example digital floor map 258) can be generated. It is noted that a DXF file is a CAD data file format based file and stands for Drawing Exchange Format or Drawing Interchange Format. Further, the DXF file, as stated above, has a file extension of .DXF and operates to enable data interoperability between a CAD file and other software entities, e.g., importing, exporting, and sharing data from the .DXF file to files associated with other software applications.

FIG. 3A depicts an example illustration 300 of an example implementation, display, and operation of the plugin 202, according to some aspects described and illustrated herein. In aspects, the plugin 202 can included as part of a digital content (e.g., a digital document) of a software entity (e.g., third party software application) accessible via the user device 102 and displayable on the user interface of the user device 102. As illustrated in FIG. 3A, the plugin 202 can be accessed by selecting a tab or user-selectable icon, which in turn results in the display of a number of additional example user-selectable icons 302 included as part of a toolbar 304. As described in detail above, in aspects, the additional user-selectable icons can include “map properties,” “add families,” “auto mapping,” “map categories,” “attach to site,” “select floors,” “data sync,” graphic sync,” “graphic sync 2D,” and “launch Nuvolo.” In aspects, additional icons can be generated and included as part of the toolbar 304 via software and firmware upgrades that can be received by the user 102 from the computing system 104. The software and firmware updates can be implemented on the user device 102 wirelessly by the computing system 104 via the communication network 106.

In aspects, upon selection of one of the additional user-selectable icons, e.g., example map properties icon 306, a pop-up digital page 308 can be displayed, which includes a plurality of additional example user selectable tabs, e.g., example floor icon 310, example location icon 312, and example asset icon 314. In aspects, upon selection of a create mapping icon 316, data representative of and associated with a particular location or locations, which is included as part of a drawing file (Revit drawing file) having a particular file format and extension (e.g., .rvt extension), can be shared with the computing system 104. It is noted that, prior to sharing the data with the computing system 104, it is determined whether an internet connection exists, in particular, whether a wireless connection exists between the plugin 202 and the computing system 104. Further, one or more authentication processes can be initiated prior to the sharing of data with the computing system 104, as described above, e.g., basic authentication, session authentication, token based authentication, and so forth. In aspects, the plugin 202 can enable integration of the Revit drawing file with one or more software entities and/or proprietary platforms of the computing system 104.

In aspects, the Revit drawing file can be generated and accessible via the user device 102, in addition to being stored locally in memory of the user device 102. In other aspects, the Revit drawing file can be generated by one or more devices that are external to the user device 102 and the computing system 104 and stored in, e.g., a cloud server, that is independent of the user device 102 and the computing system 104. The user device 102 can access the Revit drawing file stored in the cloud server via a software entity of which the plugin 202 is a part, and initiate execution of the plugin 202 to provide the computing system 104 with access to the Revit drawing file. In aspects, the Revit drawing file can comprise information about an entire building, e.g., data about each room of each floor of a hundred floor building, in addition to data relating to one or more objects within each floor of the building. In aspects, the integration of the Revit drawing file with the computing system 104 via implementation of the plugin 202 facilitates rendering of a two dimensional (2D) floor plan representation or floor plan view of every floor of, e.g., a multi-hundred floor building in an efficient and accurate manner.

FIG. 3B depicts selection of a selection of a user-selectable icon labeled “asset,” according to some embodiments described and illustrated herein. In particular, as illustrated in FIG. 3B, selection of asset icon 314 outputs a digital page that lists a plurality of assets and properties, property names, and table labels corresponding with these assets. Thereafter, a selection of the create mapping icon 316 enables sharing of data associated with these assets with the computing system 104 via the communication network 106, using the plugin 202.

FIG. 3C depicts selection of a selection of a user selectable icon labeled “add families,” according to some embodiments described and illustrated herein. In particular, as illustrated in FIG. 3C, upon selection of an example add families icon 320, an add families digital page 322 is output on the user interface of the user device 102. Thereafter, subsequent to a determination of an internet connection between the user device 102 and the computing system 104, data related to various family types included as part of the Revit drawing file is shared with the computing system 104 via the communication network 106 using the plugin 202.

FIG. 3D depicts selection of a selection of a user selectable icon labeled “Map Categories,” according to some embodiments described and illustrated herein. In particular, upon selection of a map categories icon 324, a map categories digital page 326 is output on the user interface of the user device 102. The digital page 326 provides a user with a plurality of layers (e.g., CAFM layers), a plurality of categories, and merged categories are listed. One or more types of layers and one or more types of categories can be selected from a drop-down menu. Examples of the types of layers include, e.g., amenities, assets, boundary, business unit, furniture, furniture and other background, etc., Examples of categories include abutments, air systems, analysis results, areas, audio visual devices, and examples of merged categories include boundary conditions, roof details, roofs, and stairs. These examples are non-exhaustive.

FIG. 3E depicts selection of a user selectable icon labeled “Auto mapping,” according to some embodiments described and illustrated herein. Upon selection of an auto mapping icon 328, a mapping data digital page 330 is output on the user interface of the user device 102. Further, selection of the auto mapping icon 328 initiates a plurality of subsequent actions, namely the extraction of data representative of various parameters. In aspects, the data that is extracted can corresponds to project parameters model data, level parameters model data, furniture parameters model data, and so forth. Thereafter, an auto-mapping process is implemented by the layer mapper 118 operating in conjunction with the plugin 202.

FIG. 3F depicts a selection of a user selectable icon labeled “Attach to Site,” according to some embodiments described and illustrated herein. Upon selection of an example attached to site icon 332, an attach to site digital page 334 can be output on the user interface of the user device 102. The attach to site digital page 334 can include three user-selectable tabs that can be titled “Create Campus,” “Create Site,” and “Attach to Site.” Upon selection of the Attach to Site tab 336, a plurality of drop down menus and additionally user selectable icons, including an attach icon 338 can be available for user selection. In aspects, non limiting examples of these drop down menus can include “select region name,” “select campus name,” and “site name.”

FIG. 3G depicts a selection of a user selectable icon labeled “Data Sync,” according to some embodiments described and illustrated herein. Upon selection of the example Data Sync icon 340, a data sync digital page 342 is output on the user interface of the user device 102. In particular, the data sync digital page 342 includes a plurality of additional user selectable tabs and icons, e.g., an example Start Data Sync icon 344 and a “Refresh” icon. Selection of the “Start Data Sync” icon initiates the data sync operation.

FIG. 3H depicts a selection of a user selectable icon labeled “Graphic Sync,” according to some embodiments described and illustrated herein. Upon selection of the example Graphic Sync icon 346, a graphical sync digital page 348 is output on the user interface of the user device 102.

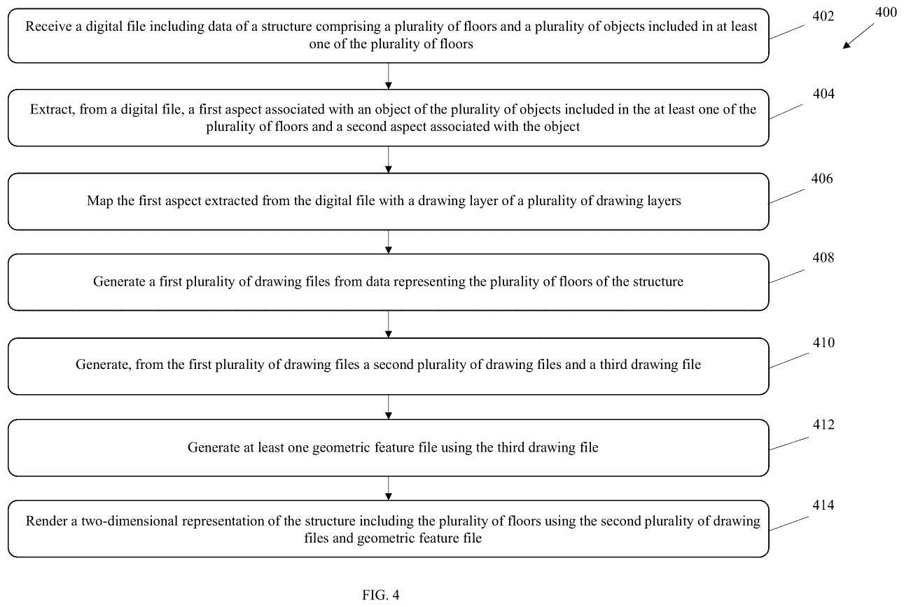

FIG. 4 illustrates an example process 400 for integrating BIM models as described herein for rendering two dimensional representations of digital content included in a digital file, in accordance with some example implementations described and illustrated herein.

At block 402, a digital file including data of a structure comprising a plurality of floors a plurality of objects included in at least one of the plurality of floors can be received. In aspects, the digital file can correspond to a Revit drawing file, as described in the present disclosure. The Revit drawing file is stored in the database 112 and locally in memory of the user device 102 and has a file format extension of .rvt. As stated above, the Revit drawing file can be generated using a 4D BIM software application, e.g., a modeling application that can be used to generate a 3D model of a building, which can be analyzed relative to time, schedule, and building progress related metrics. In aspects, a Revit drawing file comprises a variety of details regarding a structure, such as a building, in 3D. These details include, e.g., data of the architecture and design details of a building, the installation of mechanical, electrical, and plumbing components and systems at various locations in the building, and so forth. In aspects, the plurality of objects can correspond to rooms on each floors, items in each room, items in the hallways of each floor (e.g., security cameras, Wi-Fi router installations, and so forth.

At block 404, a first aspect associated with an object of the plurality of objects included in the at least one of the plurality of floors and a second aspect associated with the object can be extracted from the digital file. In aspects, the first aspect can correspond to data representing a category of the object and the second aspect can correspond to additional data representing a family of the object. The family can be classified as a subcategory within the category. As described above and illustrated in FIG. 2B, an example of a category can be a “column” and various types of columns (rectangular column, round column, and so forth) can be classified as “families” within this broader column category.

At block 406, the first aspect extracted from the digital file can be mapped to a drawing layer of a plurality of drawing layers. The first aspects corresponds to a category extracted from the digital file (e.g., Revit Drawing File) and the drawing layer can correspond to a level or portion of a computer-aided facilities management (or CAFM) file. As described above, each category of the Revit drawing file can be associated with a specific CAFM layer in a hierarchy of a plurality of CAFM layers. The CAFM layers described herein can be generated by the software entity as described herein. In aspects, each CAFM layer can correspond to, e.g., data representative of each room or office on a floor in addition to each floor of a building. Further, in aspects, each drawing layer can include and correspond to data of at least one of a floor plan, an interior wall of a structure (e.g., a building), an exterior wall of the structure, a room of the structure, an interior area of the structure, locations of security devices (e.g., cameras) at various locations in the structure, Wi-Fi hotspots installed at various locations in the structure, and different types of furniture. Further, in aspects, the mapping of the first aspect to a drawing layer corresponds to storing, in a specific location in the database 112, data representative of the first aspect of the object in association with data defining the drawing layer of the plurality of drawing layers.

At block 408, a first plurality of drawing files from data representing the plurality of floors of the structure can be generated. In aspects, each drawing file of the first plurality of drawing files has a .DWG file format-a binary file format for storing two-dimensional and three-dimensional design data and meta data. In aspects, each drawing file corresponds to data representing a respective floor of the plurality of floors of a structure, e.g., a building.

At block 410, a second plurality of drawing files corresponds to data representing visual-graphic characteristics of the plurality of objects and the plurality of floors can be generated from the first plurality of drawing files. In aspects, the visual-graphic characteristics correspond to at least one of, e.g., data representing walls, doors, furniture, windows, and so forth. In aspects, the visual-graphic characteristics can also correspond to any form or type of digital content (e.g., animation, images, video stream, and so forth). In aspects, each of the second plurality of drawing files is a Scalable Vector Graphics file having a Scalable Vector Graphics (SVG) file format. Each SVG file includes data representing, e.g., walls, doors, furniture, exit signs, stairs, windows, and so forth. Further, at least a third drawing file representing perimeter characteristics of each floor of the plurality of floors of the structure can be generated from the first plurality of drawing files. The third drawing file is a Drawing Interchange Format file having a .DXF format and the perimeter characteristics of each floor corresponds to coordinate data of the plurality of floors.

At block 412, at least one geometric feature file can be generated using the third drawing file. In aspects, the geometric feature file corresponds to a GeoJSON file having JSON file format. As stated above, a geometric feature file includes a collection of data that represents various geometric features. Geometric features can correspond to various shapes, e.g., rectangle, square, circle, etc., and these features, as included in the geometric feature file, can be utilized to represent portions of various spaces, locations, regions, and geographical features. For example, the geometric features can represent a perimeter or the bounds of a floor on a multi-floor building, districts of a city, borders of a state, and so forth. In aspects, a GeoJSON file, an example of a geometric feature file, corresponds to a file for encoding a variety of geographic data structures with the use of various geometric features, e.g., point, linestring, polygon, multipoint, multilinestring, and multipolygon. GeoJSON is an open standard geospatial data interchange format that operates to represent simple geographic features and their non spatial attributes.

At block 414, a two-dimensional representation of the structure including the plurality of floors using the second plurality of drawing files and geometric feature file are rendered. In aspects, the rendering comprises determining coordinate data of the plurality of floors from the at least the third drawing file, aligning data representing the second plurality of drawing files with the coordinate data, and overlaying data representing the at least one geometric feature file on at least one of the second plurality of files.

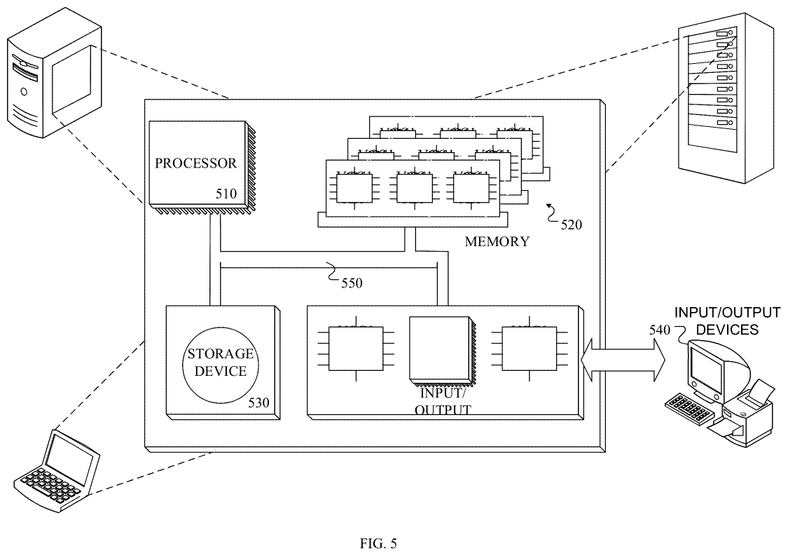

FIG. 5 shows illustrates a schematic diagram of an example computing system 500 is provided. The example computing system 500 can be implemented as the user client 102, the server system 108, and the computing device 110. In aspects, the example computing system 500 can be included in any or all of the server components discussed herein with reference to FIG. 1. The example computing system 500 includes a processor 510, a memory 520, a storage device 530, and an input/output device 540. The components 510, 520, 530, 540 are interconnected using a system bus 550. The processor 510 is capable of processing instructions for execution within the example computing system 500. In one implementation, the processor 510 is a single-threaded processor. In another implementation, the processor 510 is a multi-threaded processor. The processor 510 is capable of processing instructions stored in the memory 520 or on the storage device 530 to display graphical information for a user interface on the input/output device 540.

The memory 520 stores information within the example computing system 500. In on implementation, the memory 520 is a computer-readable medium. In one implementation, the memory 520 is a volatile memory unit. In another implementation, the memory 520 is a non-volatile memory unit. The storage device 530 is capable of providing mass storage for the example computing system 500. In one implementation, the storage device 530 is a computer-readable medium. In various different implementations, the storage device 530 can be a floppy disk device, a hard disk device, an optical disk device, or a tape device. The input/output device 540 provides input/output operations for the example computing system 500. In one implementation, the input/output device 540 includes a keyboard and/or pointing device. In another implementation, the input/output device 540 includes a display unit for displaying graphical user interfaces.

The features described can be implemented in digital electronic circuitry, or in computer hardware, firmware, software, or in combinations of them. The apparatus can be implemented in a computer program product tangibly embodied in an information carrier (e.g., in a machine-readable storage device, for execution by a programmable processor), and method steps can be performed by a programmable processor executing a program of instructions to perform functions of the described implementations by operating on input data and generating output. The described features can be implemented advantageously in one or more computer programs that are executable on a programmable system including at least one programmable processor coupled to receive data and instructions from, and to transmit data and instructions to, a data storage system, at least one input device, and at least one output device. A computer program is a set of instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

Suitable processors for the execution of a program of instructions include, by way of example, both general and special purpose microprocessors, and the sole processor or one of multiple processors of any kind of computer. Generally, a processor will receive instructions and data from a read-only memory or a random access memory or both. Elements of a computer can include a processor for executing instructions and one or more memories for storing instructions and data. Generally, a computer can also include, or be operatively coupled to communicate with, one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including by way of example semiconductor memory devices, such as EPROM, EEPROM, and flash memory devices; magnetic disks such as internal hard disks and removable disks; magneto-optical disks; and CD-ROM and DVD-ROM disks. The processor and the memory can be supplemented by, or incorporated in, ASICs (application-specific integrated circuits).

To provide for interaction with a user, the features can be implemented on a computer having a display device such as a CRT (cathode ray tube) or LCD (liquid crystal display) monitor for displaying information to the user and a keyboard and a pointing device such as a mouse or a trackball by which the user can provide input to the computer.

The features can be implemented in a computer system that includes a back-end component, such as a data server, or that includes a middleware component, such as an application server or an Internet server, or that includes a front-end component, such as a client computer having a graphical user interface or an Internet browser, or any combination of them. The components of the system can be connected by any form or medium of digital data communication such as a communication network. Examples of communication networks include, for example, a LAN, a WAN, and the computers and networks forming the Internet.

The computer system can include clients and servers. A client and server are generally remote from each other and typically interact through a network, such as the described one. The relationship of client and server arises by virtue of computer programs running on the respective computers and having a client-server relationship to each other.

In addition, the logic flows depicted in the figures do not require the particular order shown, or sequential order, to achieve desirable results. In addition, other steps can be provided, or steps can be eliminated, from the described flows, and other components can be added to, or removed from, the described systems. Accordingly, other implementations are within the scope of the following claims.

A number of implementations of the present disclosure have been described.

Nevertheless, it will be understood that various modifications can be made without departing from the spirit and scope of the present disclosure. Accordingly, other implementations are within the scope of the following claims.

One or more aspects or features of the subject matter described herein can be realized in digital electronic circuitry, integrated circuitry, specially designed ASICs, field programmable gate arrays (FPGAs) computer hardware, firmware, software, and/or combinations thereof. These various aspects or features can include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system can include clients and servers. A client and server are generally remote from each other and typically interact through a communication network. The relationship of client and server arises by virtue of computer programs running on the respective computers and having a client-server relationship to each other.

These computer programs, which can also be referred to as programs, software, software applications, applications, components, or code, include machine instructions for a programmable processor, and can be implemented in a high-level procedural and/or object-oriented programming language, and/or in assembly/machine language. As used herein, the term “machine-readable medium” refers to any computer program product, apparatus and/or device, such as for example magnetic discs, optical disks, memory, and Programmable Logic Devices (PLDs), used to provide machine instructions and/or data to a programmable processor, including a machine-readable medium that receives machine instructions as a machine-readable signal. The term “machine-readable signal” refers to any signal used to provide machine instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example, as would a processor cache or other random access memory associated with one or more physical processor cores.

To provide for interaction with a user, one or more aspects or features of the subject matter described herein can be implemented on a computer having a display device, such as for example a cathode ray tube (CRT) or a liquid crystal display (LCD) or a light emitting diode (LED) monitor for displaying information to the user and a keyboard and a pointing device, such as for example a mouse or a trackball, by which the user can provide input to the computer. Other kinds of devices can be used to provide for interaction with a user as well. For example, feedback provided to the user can be any form of sensory feedback, such as for example visual feedback, auditory feedback, or tactile feedback; and input from the user can be received in any form, including acoustic, speech, or tactile input. Other possible input devices include touch screens or other touch-sensitive devices such as single or multi-point resistive or capacitive track pads, voice recognition hardware and software, optical scanners, optical pointers, digital image capture devices and associated interpretation software, and the like.

Further non-limiting aspects or aspects are set forth in the following numbered clauses:
Clause 1: A method implemented by a computing device, the method comprising: receiving, by the computing device, a digital file including data of a structure comprising a plurality of floors and a plurality of objects included in at least one of the plurality of floors, extracting by the computing device, from the digital file, a first aspect associated with an object of the plurality of objects included in the at least one of the plurality of floors and a second aspect associated with the object, mapping the first aspect that is extracted from the digital file with a drawing layer of a plurality of drawing layers, the mapping causing the second aspect to be mapped to at least the drawing layer of the plurality of drawing layers, generating, by the computing device, a first plurality of drawing files from data representing the plurality of floors of the structure, each drawing file of the first plurality of drawing files corresponding to data representing a respective floor of the plurality of floors, generating from the first plurality of drawing files, by the computing device, a second plurality of drawing files corresponding to data representing visual-graphic characteristics of the plurality of objects and the plurality of floors and at least a third drawing file representing perimeter characteristics of each floor of the plurality of floors of the structure, generating, by the computing device, at least one geometric feature file using the third drawing file, and rendering, by the computing device, a two-dimensional representation of the structure including the plurality of floors using the second plurality of drawing files and geometric feature file.
Clause 2: The method of clause 1, wherein the structure corresponds to a building including the plurality of floors and the digital file includes a three dimensional representation of the building.
Clause 3: The method of clause 1, wherein the first aspect corresponds to data representing a category of the object and the second aspect corresponds additional data representing a family of the object, the family classified as a subcategory of the category, and the drawing layer of the plurality of drawing layers corresponds to a portion of a computer-aided facilities management (CAFM) file.
Clause 4: The method of clause 1, wherein each drawing layer of the plurality of drawing layers corresponds to at least one of: a floor plan, an interior wall of the structure, an exterior wall of the structure, a room of the structure, an interior area of the structure, locations of security devices of the structure, the security devices comprising security cameras, capabilities of Wi-Fi hotspots in the structure, or types of furniture in the structure.
Clause 5: The method of clause 1, wherein the mapping of the first aspect with the drawing layer of the plurality of drawing layers corresponds to storing, in a database communicatively coupled to the computing device, data representative of the first aspect of the object in association with data defining the drawing layer of the plurality of drawing layers.
Clause 6: The method of clause 1, wherein each of the first plurality of drawing files has a Device Working Group (DWG) file format, each of the second plurality of drawing files has a Scalable Vector Graphics (SVG) file format, and the at least the third drawing file has a Drawing Interchange Format (DXF) file format.
Clause 7: The method of clause 1, wherein the geometric feature file corresponds to a GeoJSON file format.
Clause 8: The method of clause 1, wherein the data included in the digital file is associated with a three dimensional representation of the structure.
Clause 9: The method of clause 1, wherein the rendering of the two-dimensional representation of the structure comprises determining coordinate data of the plurality of floors from the at least the third drawing file, aligning data representing the second plurality of drawing files with the coordinate data, and overlaying data representing the at least one geometric feature file on at least one of the second plurality of files.
Clause 10: The clause of claim 1, wherein the visual-graphic characteristics corresponds to at least one of: data representing walls, data representing doors, data representing furniture, or data representing windows.
Clause 11: The clause of claim 1, wherein the perimeter characteristics corresponds to coordinate data of the plurality of floors that are derived from the at least the third drawing file.
Clause 12: A system comprising one or more computers and one or more storage devices on which are stored instructions that are operable, when executed by the one or more computers, to cause the one or more computers to perform operations comprising receiving a digital file including data of a structure comprising a plurality of floors and a plurality of objects included in at least one of the plurality of floors, extracting, from the digital file, a first aspect associated with an object of the plurality of objects included in the at least one of the plurality of floors and a second aspect associated with the object, mapping the first aspect that is extracted from the digital file with a drawing layer of a plurality of drawing layers, the mapping causing the second aspect to be mapped to at least the drawing layer of the plurality of drawing layers, generating a first plurality of drawing files from data representing the plurality of floors of the structure, each drawing file of the first plurality of drawing files corresponding to data representing a respective floor of the plurality of floors, generating, from the first plurality of drawing files, a second plurality of drawing files corresponding to data representing visual-graphic characteristics of the plurality of objects and the plurality of floors and at least a third drawing file representing perimeter characteristics of each floor of the plurality of floors of the structure, generating at least one geometric feature file using the third drawing file, and rendering a two-dimensional representation of the structure including the plurality of floors using the second plurality of drawing files and geometric feature file.
Clause 13: The system of clause 12, wherein the structure corresponds to a building including the plurality of floors and the digital file includes a three dimensional representation of the building.
Clause 14: The system of clause 12, wherein the first aspect corresponds to data representing a category of the object and the second aspect corresponds additional data representing a family of the object, the family classified as a subcategory of the category, and the drawing layer of the plurality of drawing layers corresponds to a portion of a computer-aided facilities management (CAFM) file.
Clause 15: The system of clause 12, wherein each drawing layer of the plurality of drawing layers corresponds to at least one of: a floor plan, an interior wall of the structure, an exterior wall of the structure, a room of the structure, an interior area of the structure, locations of security devices of the structure, the security devices comprising security cameras, capabilities of Wi-Fi hotspots in the structure, or types of furniture in the structure.
Clause 16: The system of clause 12, wherein the mapping of the first aspect with the drawing layer of the plurality of drawing layers corresponds to storing, in a database communicatively coupled to the one or more computers, data representative of the first aspect of the object in association with data defining the drawing layer of the plurality of drawing layers.
Clause 17: The system of clause 12, wherein each of the first plurality of drawing files has a Device Working Group (DWG) file format, each of the second plurality of drawing files has a Scalable Vector Graphics (SVG) file format, and the at least the third drawing file has a Drawing Interchange Format (DXF) file format.
Clause 18: The system of clause 12, wherein: the geometric feature file corresponds to a GeoJSON file format, and the data included in the digital file is associated with a three dimensional representation of the structure.
Clause 19: The system of claim 12, wherein the rendering of the two-dimensional representation of the structure includes operations comprising determining coordinate data of the plurality of floors from the at least the third drawing file, aligning data representing the second plurality of drawing files with the coordinate data, and overlaying data representing the at least one geometric feature file on at least one of the second plurality of files.
Clause 20: A system comprising one or more computers and one or more storage devices on which are stored instructions that are operable, when executed by the one or more computers, to cause the one or more computers to perform operations comprising receiving a digital file including data of a structure comprising a plurality of floors and a plurality of objects included in at least one of the plurality of floors, extracting, from the digital file, a first aspect associated with an object of the plurality of objects included in the at least one of the plurality of floors and a second aspect associated with the object, mapping the first aspect that is extracted from the digital file with a drawing layer of a plurality of drawing layers, the mapping causing the second aspect to be mapped to at least the drawing layer of the plurality of drawing layers, generating a first plurality of drawing files from data representing the plurality of floors of the structure, each drawing file of the first plurality of drawing files corresponding to data representing a respective floor of the plurality of floors, generating, from the first plurality of drawing files, a second plurality of drawing files corresponding to data representing visual-graphic characteristics of the plurality of objects and the plurality of floors and at least a third drawing file representing perimeter characteristics of each floor of the plurality of floors of the structure, generating at least one geometric feature file using the third drawing file, and rendering a two-dimensional representation of the structure including the plurality of floors using the second plurality of drawing files and geometric feature file.

What is claimed is:

1. A method implemented by a computing device, the method comprising:
receiving, by the computing device, a digital file including data of a structure comprising a plurality of floors and a plurality of objects included in at least one of the plurality of floors;
extracting by the computing device, from the digital file, a first aspect associated with an object of the plurality of objects included in the at least one of the plurality of floors and a second aspect associated with the object;
mapping the first aspect extracted from the digital file to a drawing layer of a plurality of drawing layers, the mapping causing the second aspect to be mapped to at least the drawing layer of the plurality of drawing layers;
generating, by the computing device, a first plurality of drawing files from data representing the plurality of floors of the structure, each drawing file of the first plurality of drawing files corresponding to data representing a respective floor of the plurality of floors;
generating from the first plurality of drawing files, by the computing device, a second plurality of drawing files corresponding to data representing visual-graphic characteristics of the plurality of objects and the plurality of floors and at least a third drawing file representing perimeter characteristics of each floor of the plurality of floors of the structure;
generating, by the computing device, at least one geometric feature file using the third drawing file; and
rendering, by the computing device, a two-dimensional representation of the structure including the plurality of floors using the second plurality of drawing files and geometric feature file.

2. The method of claim 1, wherein the structure corresponds to a building including the plurality of floors and the digital file includes a three dimensional representation of the building.

3. The method of claim 1, wherein:
the first aspect corresponds to data representing a category of the object and the second aspect corresponds additional data representing a family of the object, the family classified as a subcategory of the category; and
the drawing layer of the plurality of drawing layers corresponds to a portion of a computer-aided facilities management (CAFM) file.

4. The method of claim 1, wherein each drawing layer of the plurality of drawing layers corresponds to at least one of:
a floor plan,
an interior wall of the structure,
an exterior wall of the structure,
a room of the structure,
an interior area of the structure,
locations of security devices of the structure, the security devices comprising security cameras,
capabilities of Wi-Fi hotspots in the structure, or
types of furniture in the structure.

5. The method of claim 1, wherein the mapping of the first aspect with the drawing layer of the plurality of drawing layers corresponds to storing, in a database communicatively coupled to the computing device, data representative of the first aspect of the object in association with data defining the drawing layer of the plurality of drawing layers.

6. The method of claim 1, wherein:
each of the first plurality of drawing files has a Device Working Group (DWG) file format;
each of the second plurality of drawing files has a Scalable Vector Graphics (SVG) file format; and
the at least the third drawing file has a Drawing Interchange Format (DXF) file format.

7. The method of claim 1, wherein the geometric feature file corresponds to a GeoJSON file format.

8. The method of claim 1, wherein the data included in the digital file is associated with a three dimensional representation of the structure.

9. The method of claim 1, wherein the rendering of the two-dimensional representation of the structure comprises:
determining coordinate data of the plurality of floors from the at least the third drawing file;
aligning data representing the second plurality of drawing files with the coordinate data; and
overlaying data representing the at least one geometric feature file on at least one of the second plurality of files.

10. The method of claim 1, wherein the visual-graphic characteristics corresponds to at least one of: data representing walls, data representing doors, data representing furniture, or data representing windows.

11. The method of claim 1, wherein the perimeter characteristics corresponds to coordinate data of the plurality of floors that are derived from the at least the third drawing file.

12. A system comprising one or more computers and one or more storage devices on which are stored instructions that are operable, when executed by the one or more computers, to cause the one or more computers to perform operations comprising:
receiving a digital file including data of a structure comprising a plurality of floors and a plurality of objects included in at least one of the plurality of floors;
extracting, from the digital file, a first aspect associated with an object of the plurality of objects included in the at least one of the plurality of floors and
a second aspect associated with the object;
mapping the first aspect extracted from the digital file to a drawing layer of a plurality of drawing layers, the mapping causing the second aspect to be mapped to at least the drawing layer of the plurality of drawing layers;
generating a first plurality of drawing files from data representing the plurality of floors of the structure, each drawing file of the first plurality of drawing files corresponding to data representing a respective floor of the plurality of floors;
generating, from the first plurality of drawing files, a second plurality of drawing files corresponding to data representing visual-graphic characteristics of the plurality of objects and the plurality of floors and at least a third drawing file representing perimeter characteristics of each floor of the plurality of floors of the structure;
generating at least one geometric feature file using the third drawing file; and
rendering a two-dimensional representation of the structure including the plurality of floors using the second plurality of drawing files and geometric feature file.

13. The system of claim 12, wherein the structure corresponds to a building including the plurality of floors and the digital file includes a three dimensional representation of the building.

14. The system of claim 12, wherein:
the first aspect corresponds to data representing a category of the object and the second aspect corresponds additional data representing a family of the object, the family classified as a subcategory of the category; and
the drawing layer of the plurality of drawing layers corresponds to a portion of a computer-aided facilities management (CAFM) file.

15. The system of claim 12, wherein each drawing layer of the plurality of drawing layers corresponds to at least one of:
a floor plan,
an interior wall of the structure,
an exterior wall of the structure,
a room of the structure,
an interior area of the structure,
locations of security devices of the structure, the security devices comprising security cameras,
capabilities of Wi-Fi hotspots in the structure, or
types of furniture in the structure.

16. The system of claim 12, wherein the mapping of the first aspect with the drawing layer of the plurality of drawing layers corresponds to storing, in a database communicatively coupled to the one or more computers, data representative of the first aspect of the object in association with data defining the drawing layer of the plurality of drawing layers.

17. The system of claim 12, wherein:
each of the first plurality of drawing files has a Device Working Group (DWG) file format;
each of the second plurality of drawing files has a Scalable Vector Graphics (SVG) file format; and
the at least the third drawing file has a Drawing Interchange Format (DXF) file format.

18. The system of claim 12, wherein:
the geometric feature file corresponds to a GeoJSON file format; and
the data included in the digital file is associated with a three dimensional representation of the structure.

19. The system of claim 12, wherein the rendering of the two-dimensional representation of the structure includes operations comprising:
determining coordinate data of the plurality of floors from the at least the third drawing file;
aligning data representing the second plurality of drawing files with the coordinate data; and
overlaying data representing the at least one geometric feature file on at least one of the second plurality of files.

20. A system comprising one or more computers and one or more storage devices on which are stored instructions that are operable, when executed by the one or more computers, to cause the one or more computers to perform operations comprising:
receiving a digital file including data of a structure comprising a plurality of floors and a plurality of objects included in at least one of the plurality of floors;
extracting, from the digital file, a first aspect associated with an object of the plurality of objects included in the at least one of the plurality of floors and a second aspect associated with the object;
mapping the first aspect extracted from the digital file to a drawing layer of a plurality of drawing layers, the mapping causing the second aspect to be mapped to at least the drawing layer of the plurality of drawing layers;
generating a first plurality of drawing files from data representing the plurality of floors of the structure, each drawing file of the first plurality of drawing files corresponding to data representing a respective floor of the plurality of floors;
generating, from the first plurality of drawing files, a second plurality of drawing files corresponding to data representing visual-graphic characteristics of the plurality of objects and the plurality of floors and at least a third drawing file representing perimeter characteristics of each floor of the plurality of floors of the structure;
generating at least one geometric feature file using the third drawing file; and
rendering a two-dimensional representation of the structure including the plurality of floors using the second plurality of drawing files and geometric feature file.
